(19) United States
(12) Patent Application Publication
(10) Pub. No.: US 2005/0078607 A1
(43) Pub. Date: Apr. 14, 2005

(54) Method and frame for "in-band" path failure detection and localization within an SDH/SONET network domain

(75) Inventors: Alberto Bellato, Milano (IT); Vincenzo Sestito, Milano (IT); Pietro Vittorio Grandi, Milano (IT)

Correspondence Address: SUGHRUE MION, PLLC, 2100 PENNSYLVANIA AVENUE, N.W., SUITE 800, WASHINGTON, DC, 20037, US

(73) Assignee: ALCATEL

(21) Appl. No.: 10/792,802

(22) Filed: Mar. 5, 2004

(30) Foreign Application Priority Data
Oct. 9, 2003 (EP) 03292497.9

(51) Int. Cl. G01R 31/08

(52) U.S. Cl. 370/248; 370/242

(57) ABSTRACT

It is disclosed a method for in-band path failure detection localization in a SDH/SONET network, the network comprising at least one network domain, the method comprises the steps of defining at least one path (PATH) through which SDH/SONET frames are transmitted and is characterized by coding K3 byte of POH, for SDH technology, or coding the Z4 byte of STS1 POH, for SONET technology. Bits 1-6 of byte K3 or Z4 are coded for providing: a node identifier indicating a node detecting a failure; Remote Defect Indication information; and information relating to the fact that a failure is external or internal to a network domain.

This application is based on, and claims the benefit of, European Patent Application No. 03292497.9 filed on Oct. 9, 2003, which is incorporated by reference herein.

### BACKGROUND OF THE INVENTION

1. Field of the Invention

The present invention relates to SDH/SONET telecommunication networks and in particular to a method and corresponding frame for providing “in band” path failure detection and localization. In other words, the present invention relates to a path failure detection and localization mechanism having a logic that is distributed in the various nodes of a SDH/SONET network.

2. Description of the Prior Art

The deregulation occurred in the last years on telecommunication networks has frequently led to a multi-operator environment, where traffic may be carried through before being terminated by an actual user.

Thus, a generic path may “pass-through” different network domains with, consequently, the need to be managed and/or to be protected by each operator.

Specifically, the need to discriminate the occurrence of a possible failure within/without a domain, so as to localize the fault detected is a key issue for properly activating any method of traffic restoration/protection.

A known mechanism for activating monitoring (and also protection) functionalities in an SDH network domain is the so-called tandem connection (TC). Such a mechanism has been already standardized under ITU-T G.707 (see annex C). A Tandem Connection is defined as a group of VC-ns which are transported and maintained together through one or more tandem line systems, with the constituent VC payload capacities unaltered. Note that in support of the layered overhead approach used in SDH, the Tandem Connection sub-layer falls between the multiplex section and path overhead layers (i.e. the original Regenerator section, Multiplex section, and Path functional overhead layering evolves to Regenerator section, Multiplex section, Tandem Connection and Path layers).

The Tandem Connection mechanism thus utilizes proper bytes of POH different from those normally used for end-to-end monitoring (typically B3, C2, and J1 bytes for VC4/VC3 paths). The Tandem Connection has been typically developed for serially arranged different operator network domains, namely for network domains of different telecom operators that are serially passed-through by a certain path.

In such a scenario (serially arranged different operator network domains) the problem with the standard Tandem Connection mechanism is related to both maintenance and service level agreement operations affecting a path. In case of claims from a final user, the operator finally charging such a final user can not understand which of the intermediate serially arranged operators has provided a fault-affected network resulting in a failured path.

In order to avoid such an inconvenience, the Standard has provided for a further byte, N1 byte of VC3/VC4 POH that can be acceded by the intermediate telecom operator. An intermediate operator, at the input of a path in its network domain, writes any possible error coding values and external alarm conditions in the N1 byte and transports such information at the egress end node of its network, namely the path end node.

Thus, the known Tandem Connection mechanism is rather effective in case of serially arranged different operator network domains but it is completely uneffective and unusable in case of nested network domains. In the first case, a certain path runs from an ingress end node to an egress end node of a first network domain and then passes through, serially, a second network domain, a third network domain, . . . . In the second case, a certain path runs from an ingress end node to an egress end node of a main network domain passing through the ingress nodes of the first, the second and the n-th intermediate network domains and then through the egress nodes of the n-th, . . . , the second and the first intermediate network domains. It will become clear to the man skilled in the art that if an inner telecom operator activates a Tandem Connection for monitoring its domain, such an operation squelches any Tandem Connection possibly activated by an operator that is external to it. Thus, in other words, the TC activated by the main operator becomes useless because the nested operators have used the same bytes for writing information related to their own network status.

Thus, the Tandem Connection functionality conceived within SDH technology fits a network topology where different operators manage intermediate domains serially connected: in these domains each operator can access the N1 byte of VC3/VC4 POH of the Higher Order VC (HOVC) for internal path monitoring, terminating the functionality at the NE's ingressing-egressing its domain.

Fault localization is currently supported through control plane (DCC) by centralized and distributed management. In a SDH or SONET network, all the alarm information are notified by the various network elements to the manager through the control plane. Thus, the DCC bytes (D1-D3 in SDH-RSOH or Sonet-Section Overhead and D4-D12 in SDH-MSOH or Sonet-Line Overhead) are used as communication channels for transmitting such information and form the supervision/control channel. In turn, the supervision/control channel is separated from the communication channel or data plane (situations could happen wherein the control plane is affected by a failure and the data plane is not or vice versa).

Fault localization through control plane is rather slow due to the different functional layers to be processed at each Network Element and, consequently, the possible update of network conditions due to a restoration process becomes critical in terms of response time for a fast re-allocation of available resources.

Finally, just for the purpose of providing a complete description, it should be said that in the OTH optical layer, the nested Tandem Connection functionality is defined. Whilst in the SDH domain a single byte N1 is defined (as said above), in the OTH case, six Tandem Connection N1-like bytes are provided, each byte being for a single level. Thus, six different information could be written in the same path and six parallel processes could be elaborated. Every nested telecom operator is allowed to accede to one only of the dedicated fields. In any case, the scope of the present patent application does not extend to the optical layer.

### SUMMARY OF THE INVENTION

In view of the above, the Applicant has perceived the need to provide a method and corresponding frame for “in band” higher order path failure detection and localization.

The problem to solve by the present invention could be seen in providing an embedded communication channel, namely a channel within the bandwidth of a synchronous SDH/SONET signal, allowing for failure detection, failure localization and possibly providing information about the need to start a restoration process.

According to the present invention, a proper byte from POH is used, preferably K3 byte is used for SDH applications, Z4 byte is used for SONET applications.

According to the present invention, at least bits 5 and 6 of K3/Z4 are used for loading the following information: RDI (Remote Defect Indication) and “External failure/Internal failure”.

Profitably, bits 1-4 of byte K3 o Z4 are coded so that they carry a node identifier indicating a node detecting a failure.

The present invention will become fully clear after reading the following detailed description, to be given by way of example only and not with the object of limiting it, having reference to the attached sheets of drawings.

### BRIEF DESCRIPTION OF THE DRAWINGS

In the drawings:

FIG. 1 is a diagrammatic representation of three serially arranged different network domains;

FIGS. 2a and 2b are diagrammatic representations of nested network domains;

FIG. 3a is a diagrammatic representation of a VC-4 frame;

FIG. 3b is a diagrammatic representation of K3 byte according to the present invention;

FIGS. 4-8 are diagrammatic representations of possible scenarios that are managed by the basic mechanism according to the present invention; and

FIGS. 9-14 are diagrammatic representations of possible scenarios that are managed by the improved mechanism according to the present invention.

### BEST MODE FOR CARRYING OUT THE INVENTION

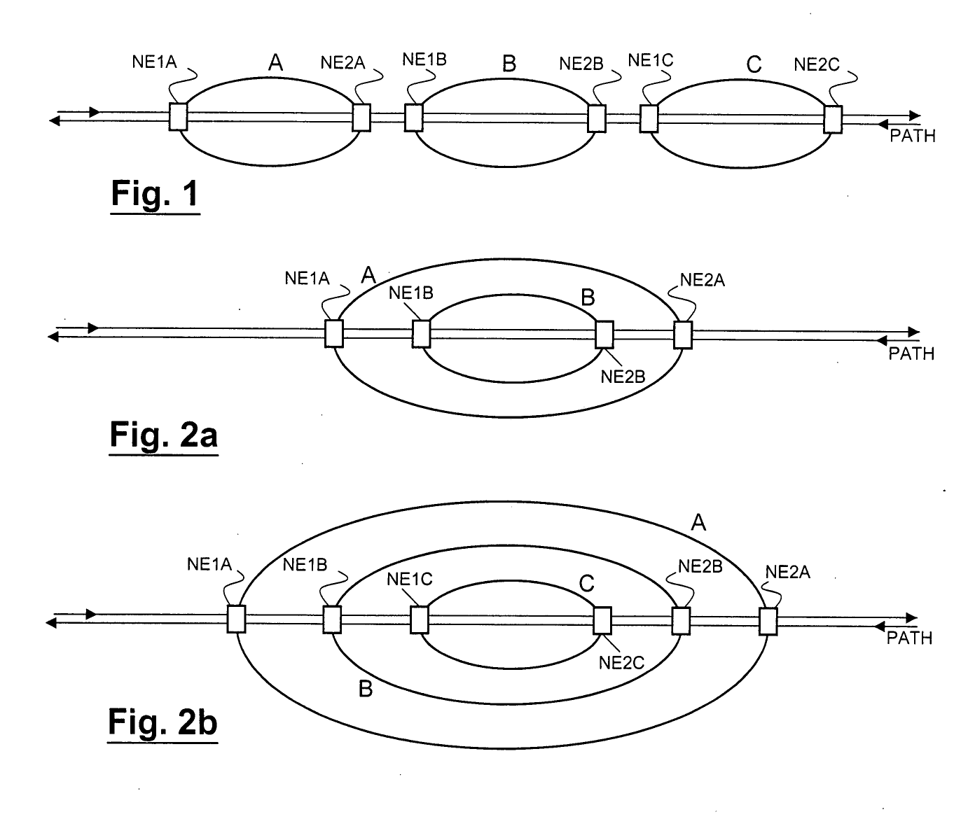

FIG. 1 shows, in a schematic manner, an example of three serially arranged different network domains that are passed through by a certain bidirectional path. Whilst the number of paths in a network could be of the order of thousands, only one is represented for clarity reasons. Furthermore, only the end nodes of the passed-through network domains are represented for the very same reason. The same applies to the other FIGS. 2a and 2b.

The path originates in end node NELA and terminates in end node NE2C of the network domain C. From NELA to NE2C it passed through the end nodes NE2A, NE1B, NE2B, NE1C of the serially arranged network domains B and C, respectively. In a similar network arrangement, the Tandem Connection mechanism operates sufficiently effectively.

The standard TC mechanism is not operable in a configuration of nested network domains as in FIGS. 2a and 2b. According to the arrangement of FIG. 2a, a path (originating in end node NEA and terminating in end node NE2A of network domain A) passes through the end nodes NE1B and NE2B. The end nodes belonging to network domain B (NEB1, NEB2), have to forward N1 byte generated each other by NEA1 and NEA2, transparently across the domain: thus, no further Tandem Connection may be activated within domain B.

In the arrangement of FIG. 2b, the situation is still more complicated and no TC can be activated within domains B and C. In fact, each intermediate end node NE1B, NE1C, NE2B and NE2C rewrites status information in the same byte N1.

The present invention is applicable both in the first and in the second configurations, it does not replace the TC mechanism but it independently from it.

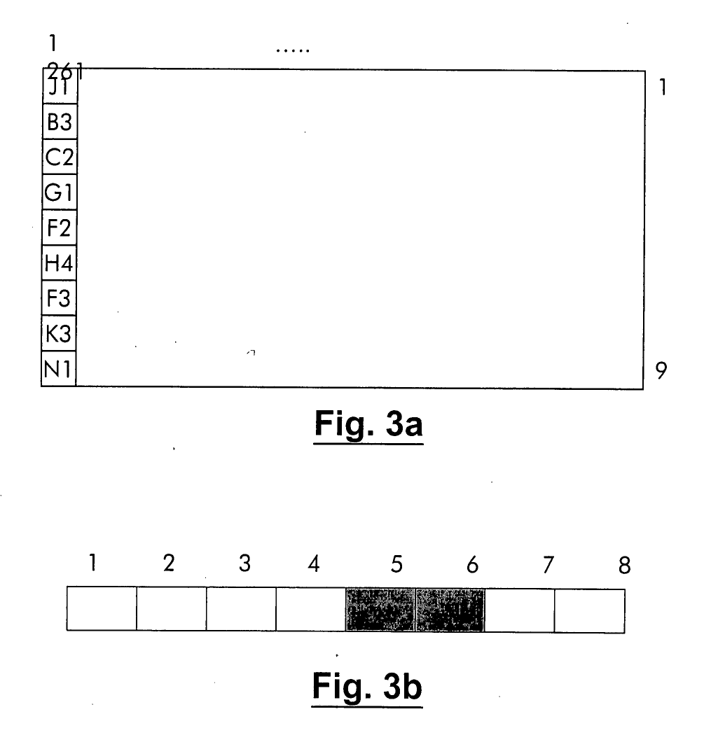

It is known that the SDH-VC-4-XcNC-4NC-3 POH consists of 9 bytes denoted J1, B3, C2, G1, F2, H4, F3, K3 and N1 (see FIGS. 11-1, 7-3 and 7-4 of ITU-T G.707 and FIG. 3a of the present application). These bytes are classified as follows:
Bytes or bits used for end-to-end communication with independent payload function: J1, B3, C2, G1, K3 (b1-b4).
Payload type specific bytes: H4, F2, F3.
Bits reserved for future international standardization: K3 (b5-b8).
Byte which can be overwritten in an operator domain (without affecting the end-to-end performance monitoring facility of the byte B3): N1. According to ITU-T G. 707, the Automatic Protection Switching (APS) channel (bits b1-b4 of K3) are allocated for APS signalling for protection at the VC-4/3 path levels. Bits 7 and 8 of K3 are reserved for a higher order path data link. The ITU-T G. 707 further states that bits b5-b6 of K3 are spare and are allocated for future use. These bits have no defined value and the receiver is required to ignore their content.

The present invention obtains the result of discriminating a path failure occurred inside a domain rather then outside. The present invention achieves such a result by using a proper encoding of K3 byte of VC4/VC3 POH (for SDH technology) or Z4 byte of STS1 POH (for SONET technology).

With reference, for instance, to FIG. 2a, for any path passing-through both domains, the NE's ingressing-egressing Domain A, (i.e. NEA1, NEA2) are supposed to handle Tandem Connection functionality for the monitoring and, possibly the protection of the interested path.

For any HO path passing-through both domains, NE's ‘ingressing-egressing’ Domain A, (i.e. NE 1, NE n) are supposed to handle Tandem Connection functionality for the monitoring and, possibly the protection of the interested path.

In particular, within the nested domains, the K3/Z4 byte is managed so as to encode specific indication for Near End/Far End fault detection in bits 5-6. Specifically, according to a preferred embodiment of the invention, bit 5 is used for indicating RDI (Remote Defect Indication) and bit 6 is used for indicating “External failure/Internal failure”. It should be understood that the scope of the present invention equally covers a different (for instance the opposite) use of bits 5 and 6 of byte K3/Z4.

As said above, this solution is aligned with current SDH/SONET standard recommendations considering those bits respectively “for future use” and “for future growth”.

Besides, this solution is compatible with the handling of possible path/trail protection schemes within the domain, based on protocol exchange message in bits 1-4 of K3 byte, as already specified by ITU-T G. 707/G.841 standard recommendations.

A further issue that an operator might want approach is the fault localization: then, not only the capability to distinguish Internal/External failure (supported by bits 5-6) will be provided, but also the possibility to localize the span (or link) which is fault affected. This feature becomes pretty attractive when path restoration methods (both centralized and distributed) are used within the domain: fault localization allows the operator to re-allocate efficiently available resources of connectivity.

Specifically, when path restoration is used for traffic survivability, a path protection scheme based on protocol is very unlikely to be used.

Then, bits 1-4 of K3/Z4 byte can be used for encoding a node identifier indicating the network element, inside the domain, detecting the path failure. This information should be forwarded and backwarded (RDI) to the NE's ingressing/egressing that domain and then to the manager.

The need to support fault localization on networks with more than 16 nodes, could be matched by multi-framing the indication of node identifier on two or more consecutive K3 byte (i.e. 8 bits or more).

Thus, ingress and egress end nodes to a network domain to be monitored identify an Internal TCM sublayer. Two new atomic functions are defined for sourcing and sinking the Internal Tandem Connection (ITC) according to the present invention: ITC-TT_So and ITC-TT_Sk. Furthermore, a new maintenance signal is defined for maintenance operations within the ITC sublayer: Internal VC-AIS (IVC-AIS). Indeed, IVC-AIS is similar to VC-AIS, with the exception that also K3 byte of POH is valid and is not all “1”s as in the known VC-AIS.

According to the present invention, the management of the internal TCM sublayer is performed only by ingress and egress nodes of main resources and no action is performed by the nodes intermediate to the network domain.

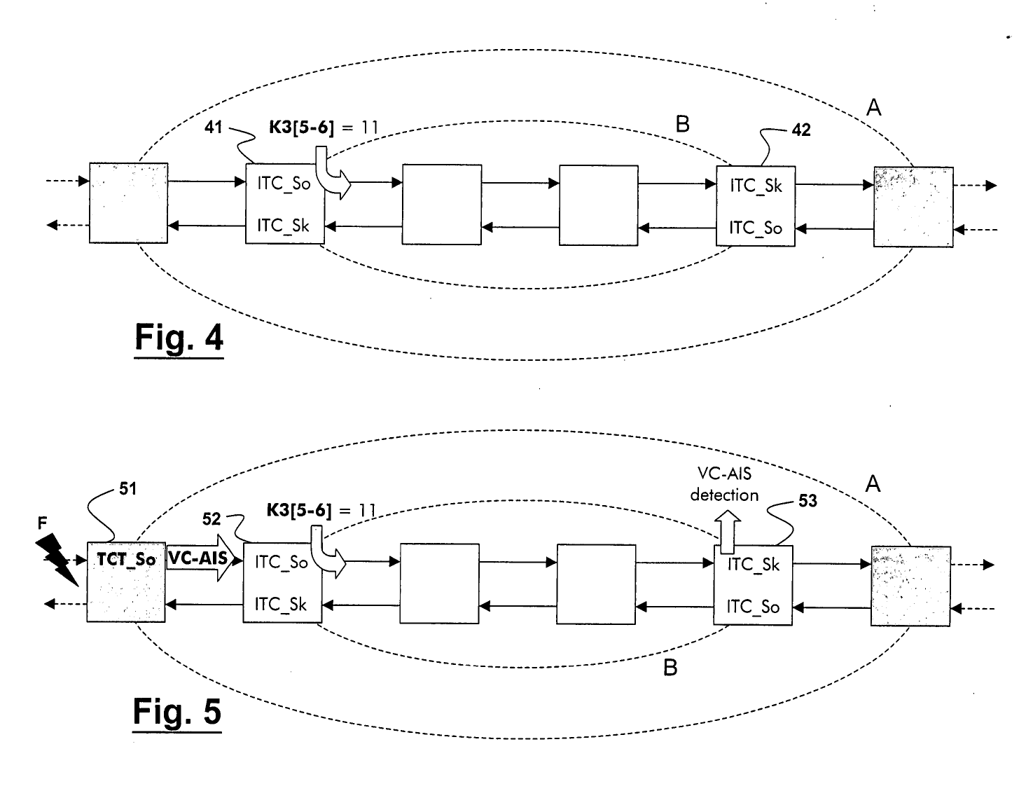

A possible failure coding according to the present invention is given, by way of example only, in the following Table 1 and will be explained through the examples of FIGS. 4-8.

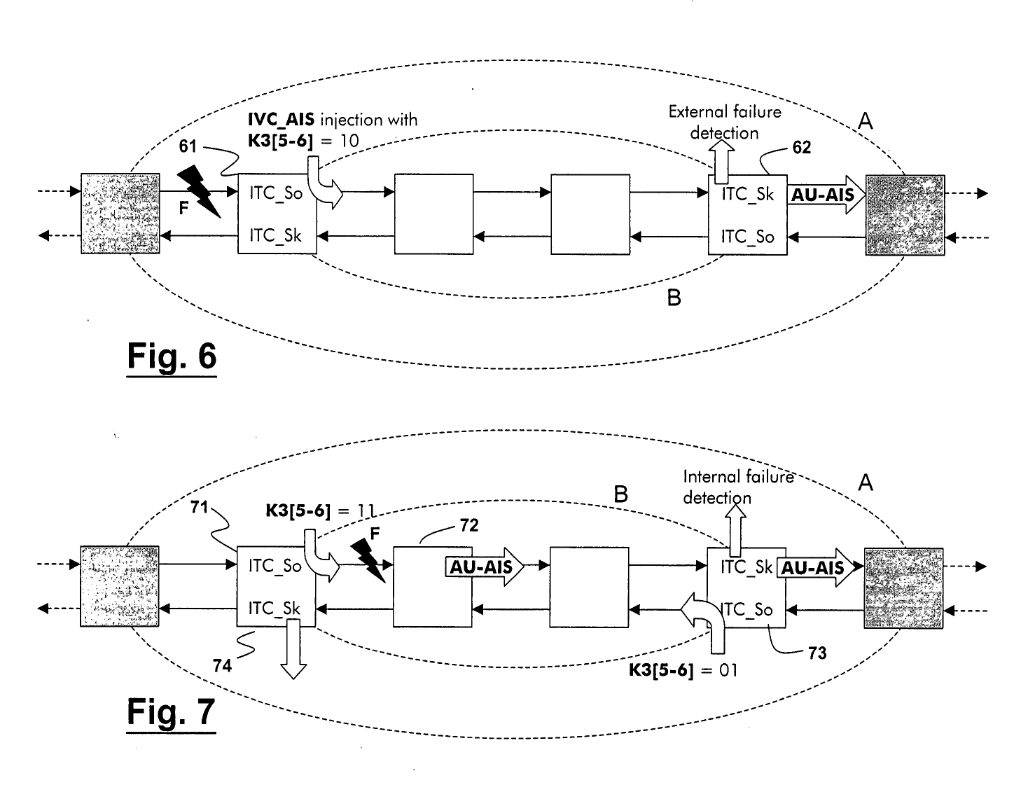

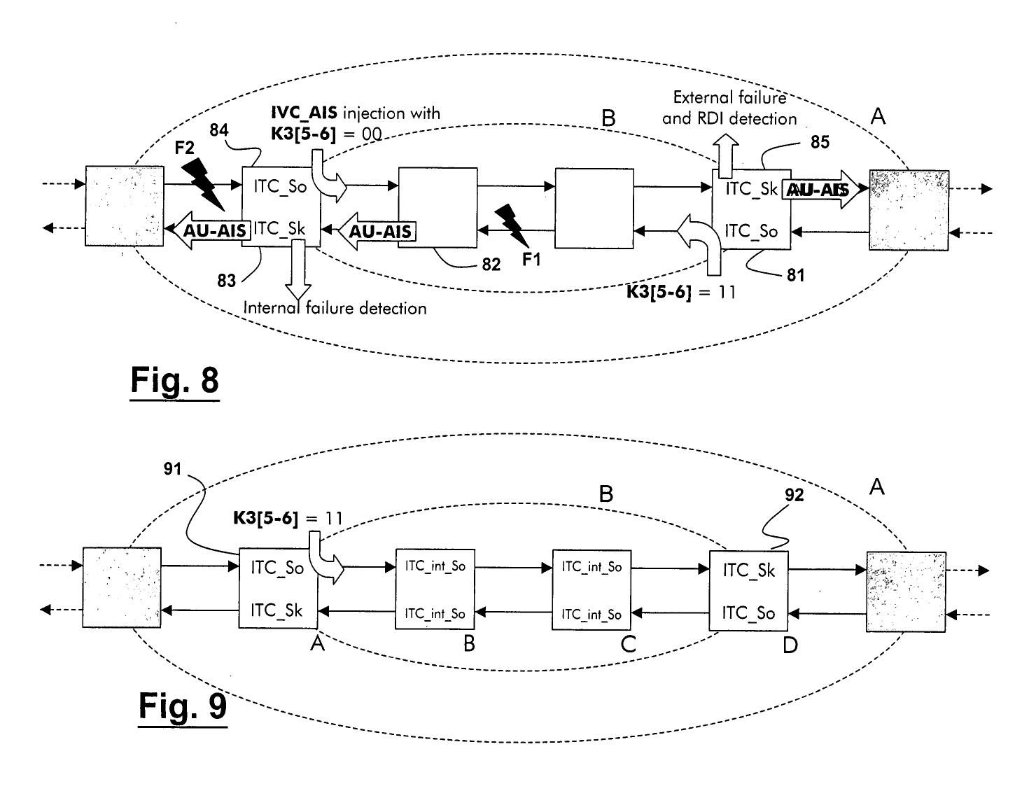

TABLE 1

| | Injected | K3 | Egress Node | Protec- |
|---|---|---|---|---|
| Signal | Maintenance | [5-6] | Consequent | tion |
| Status | Signal | value | Action | Trigger? |
| 1 | No Consequent | 11 | No Consequent | NO |
| | Action on payload | | action | |
| 2 | IVC-AIS injected in | 10 | AU-AIS | NO |
| | Ingress Node | | | |
| 3 | AU-AIS injected in | NA | AU-AIS | YES |
| | intermediate node | | | |
| 4 | No consequent | 01 | No Consequent | YES |
| | action on payload | | Action | |
| 5 | IVC-AIS injected in | 00 | AU-AIS | YES |
| | ingress node | | | |

Wherein:
Signal Status # 1: no failure condition detected in ingress node (incoming normal signal/VC-AIS received)—see examples of FIGS. 4 and 5;
Signal Status # 2: Failure Detection in ingress node (external failure)—see example of FIG. 6;
Signal Status # 3: Failure Detection in intermediate node (internal failure)—see example of FIG. 7;
Signal Status # 4: Failure Detected in backward direction—see example of FIG. 7; and
Signal Status # 5: Failure Detection in ingress node and failure detected in backward direction—see example of FIG. 8.
In the examples of FIGS. 4-8 there are illustrated a number of signal status conditions for the network domain configuration of FIG. 2a. For the purposes of clarity, the domains are schematically illustrated wherein only the nodes passed through by a path in question are shown. The gray network elements are those belonging to domain A and the white ones are those belonging to domain B. The Figures will be schematically explained through the corresponding reference signs.

With reference to FIG. 4, a “no alarm condition” is illustrated.
41. During normal condition, (i.e. no SSF is detected in the ingress node of the domain to be monitored), K3[5-6] bits are overwritten to the value “11” (see Table 1).
42. The ITC_TT_Sk function detects no alarm conditions: no protection mechanism is triggered within the domain and no consequent action is performed.

With reference to FIG. 5, a condition of external failure (namely a failure external to main domain A) with external TCM is illustrated.
51. Upon detection of an SSF condition, the standard TC_TT_So function generates a VC-AIS, carrying the incoming AIS indication. K3 [5-6] bits are overwritten to the value “11” according to Table 1 coding.
52. Internal TC_So behaves as if it were in normal conditions: K3 [5-6] bits are overwritten to the value “11” according to Table 1 coding.
53. Upon detection of C2=“FF” and K3 [5-6]=“11”, the ITC_TT_Sk function detects an incoming VC-AIS (i.e., normal condition): no protection mechanism is triggered within the domain B and no consequent action is performed.

With reference to FIG. 6, a condition of failure external to domain B but internal to domain A is illustrated.
61. Upon detection of an SSF condition (incoming AIS), the ITC_TT_So function generates an internal VC-AIS carrying the indication of external failure, namely K3 [5-6]=“10”.
62. Upon detection of C2=“FF” and K3 [5-6]=10, the ITC_TT_Sk function detects that an external failure occurred: no protection mechanism is triggered within the domain and an AU-AIS signal is generated to domain A end node.

With reference to FIG. 7, a condition of internal failure, namely of failure internal to domain B, is illustrated.
71. Internal TC_So generates K3 [5-6] to “11” value.
72. The intermediate node detecting a failure condition generates an AU-AIS.
73. Upon detection of AU-AIS, the ITC_TT_Sk function detects an internal failure: the protection mechanism can be triggered within the domain and AU-AIS is regenerated. ITC_Sk reports to ITC_So that a failure was detected, in order to send RDI indication (i.e., K3 [5-6]=“01”).
74. The ITC_TT_Sk function detects RDI indication carried over K3 [5-6].

Finally, with reference to FIG. 8, a condition of external failure with backward failure is illustrated.
81. Starting from a “no failure condition”, the internal TC_So generates K3 [5-6] to “11” value.
82. The intermediate node detecting a failure condition generates an AU-AIS.
83. The ITC_Sk of domain B reports to ITC_So that a failure was detected in order to send RDI indication.
84. Upon detection of an SSF condition (incoming AIS), the ITC_TT_So function generates an internal VC-AIS. As it is also present an RDI request, the code K3 [5-6]=“00” is injected.
85. Upon detection of C2=“FF” and K3 [5-6]=“00”, the ITC_TT_Sk function detects that an external failure occurred in the forward direction and an internal failure occurred in the backward direction. As a consequence, the protection mechanism is triggered within the domain and an AU-AIS signal is generated.

The above process can be further improved for managing fault localization by using similar concepts as above. Ingress and egress nodes to the domain to be monitored identify an internal TCM sublayer (ITCM); two new atomic functions are defined for sourcing and sinking the internal tandem connection, ITC TT_So and ITC_TT_Sk, respectively; and a new maintenance signal is defined for maintenance operations within the ITC sublayer, such a new maintenance signal is termed Internal VC-AIS (briefly, IVC-AIS). The difference resides in the fact that intermediate nodes can generate Internal VC-AIS maintenance signal in case of a failure occurred internally to a domain, instead of injecting simply AU-AIS. A new atomic function (ITC_int_So) is defined for internal tandem connection management at the nodes that are intermediate in the domain.

In addition to the coding of bits 5-6 of K3, bits 1-4 of such a byte carry a node identifier indicating the node detecting a failure. Possibly, a multiframe arrangement could be provided for network domains comprising more than sexteen nodes.

A possible improved failure coding, including failure detection features, according to the present invention is given, by way of example only, in the following Table 2 and to the examples of FIGS. 9-14.

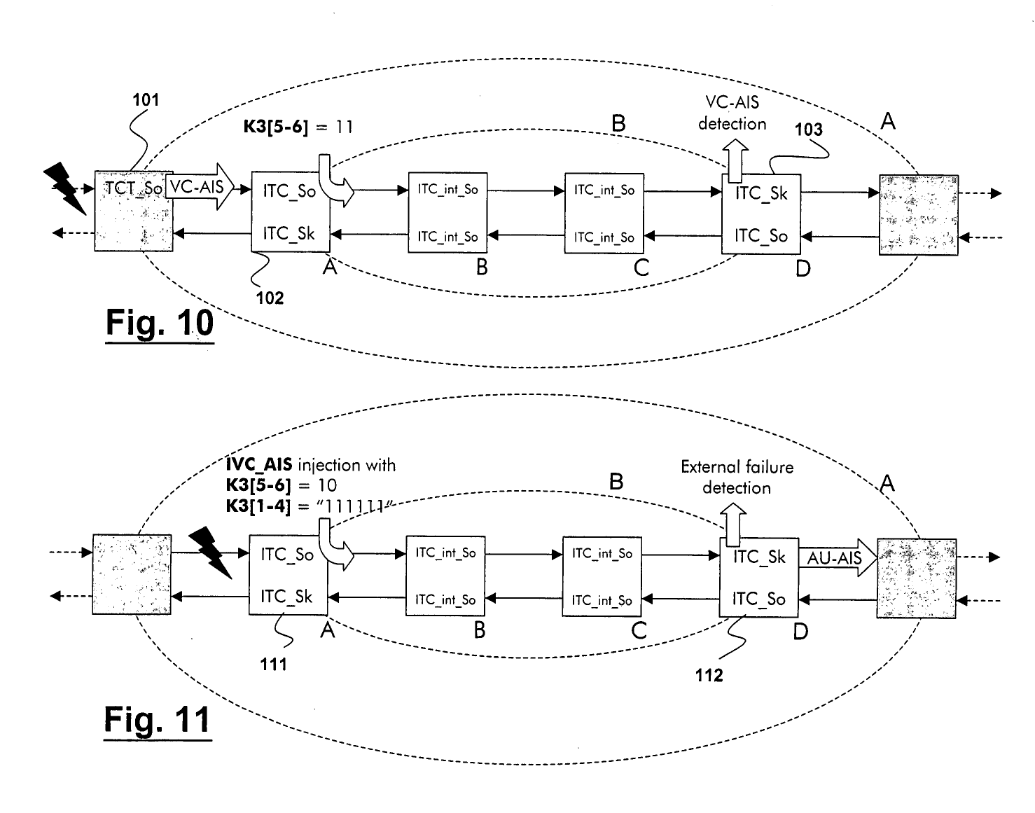

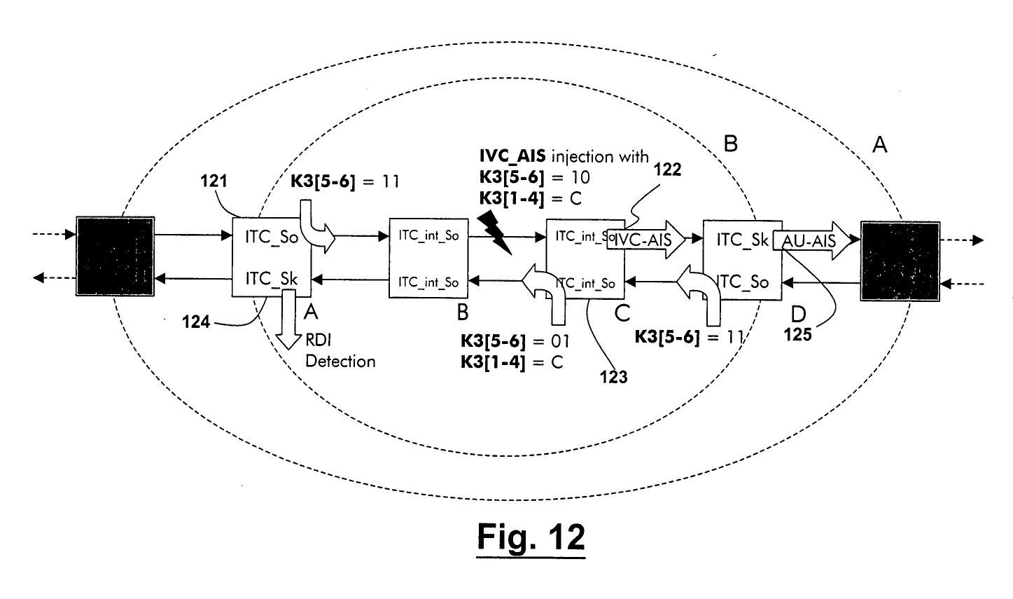

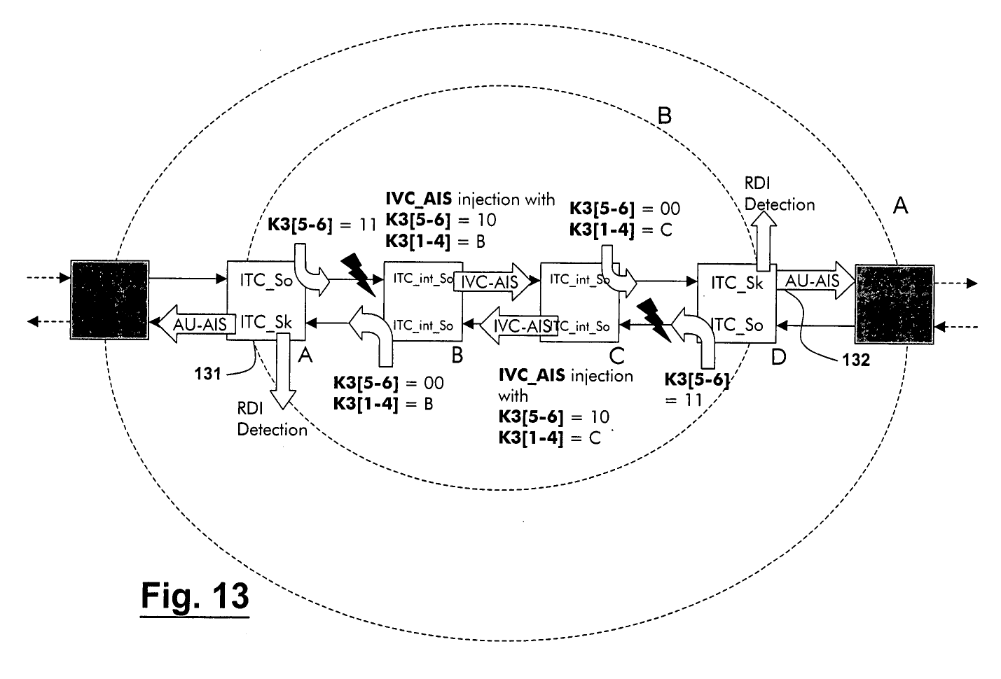

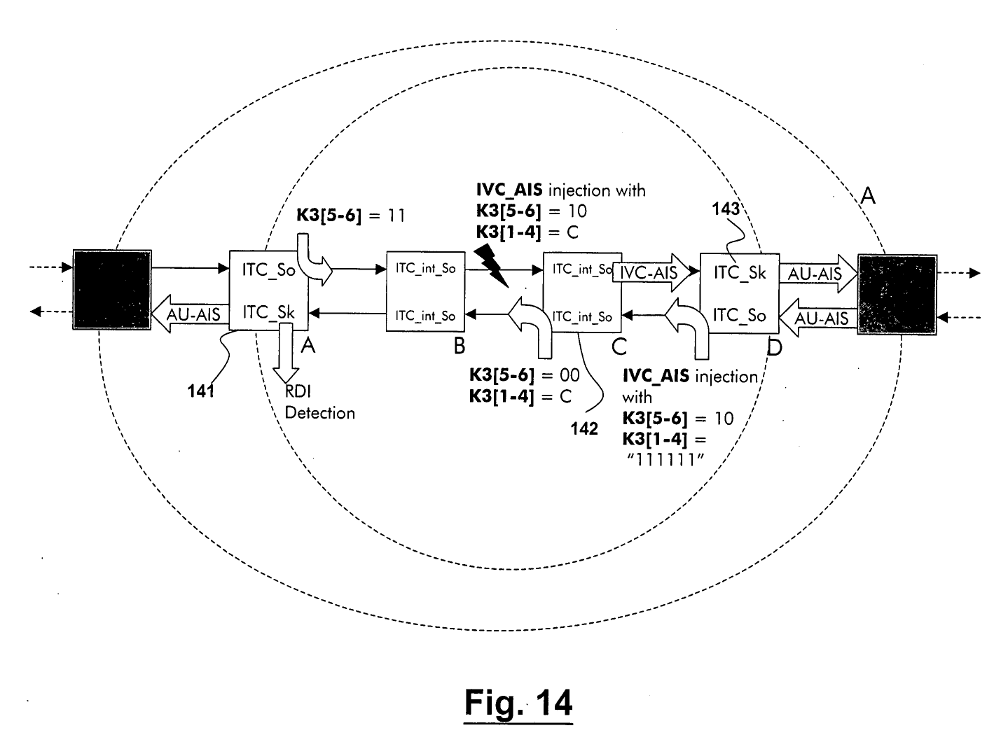

TABLE 2

| | Injected | K3 | K3 | Egress Node | |
|---|---|---|---|---|---|
| Signal | Maintenance | [5-6] | [1-4] | Consequent | Protection |
| Status | Signal | Value | Value | Action | Trigger? |
| 1 | No Consequent | 11 | NA | No Consequent | NO |
| | Action on payload | | | action | |
| 2 | IVC-AIS injected | 10 | 1111 | AU-AIS | NO |
| | in Ingress Node | | | | |
| 3 | IVC-AIS injected | 10 | Identifier of | AU-AIS | YES |
| | in intermediate | | the node | | |
| | node | | detecting | | |
| | | | the failure | | |
| 4 | No consequent | 01 | Identifier of | No Consequent | YES |
| | action on payload | | the node | Action | |
| | | | detecting | | |
| | | | the failure | | |
| 5 | IVC-AIS injected | 00 | Identifier of | AU-AIS | YES |
| | in intermediate | | the node | | |
| | node | | detecting | | |
| | | | the failure | | |
| 6 | IVC-AIS injected | 00 | Identifier of | AU-AIS | YES |
| | in ingress node | | the node | | |
| | | | detecting | | |
| | | | the failure | | |

Wherein:
Signal Status # 1: no failure condition detected in ingress node (incoming normal signal/VC-AIS received)—see examples of FIGS. 9 and 10;
Signal Status # 2: Failure Detection in ingress node (external failure)—see example of FIG. 11;
Signal Status # 3: Failure Detection in intermediate node (internal failure)—see example of FIG. 12;
Signal Status # 4: Failure Detected in backward direction—see example of FIG. 12;
Signal Status # 5: Failure Detection in intermediate node and failure detected in backward direction—see example of FIG. 13; and
Signal Status # 6: Failure Detection in ingress node and failure detected in backward direction—see example of FIG. 14.

Before starting to describe the mechanisms for failure detection according to the present invention, it should be remarked that each node belonging to domain B has a node identifier assigned. The identifier is inserted in bits 1-4 of K3 when generating internal VC-AIS. A number of identifier mapping procedures are possible but they will not described as they do not form a part of the present invention.

According to the present invention, ingress and egress nodes define the sublayer internal TC activating Internal Tandem Sk and So functions. The intermediate nodes manage Internal Tandem Connection So function.

With reference to FIG. 9, a “no alarm condition” is illustrated.
91. During normal condition, (i.e. no SSF is detected in the ingress node of the domain to be monitored), K3[5-6] bits are overwritten to the value “11” (see Table 2).
92. The ITC_TT_Sk function detects no alarm conditions: no protection mechanism is triggered within the domain and no consequent action is performed.

With reference to FIG. 10, an external failure condition with external TCM is illustrated.
101. Upon detection of an SSF condition, the standard TC_TT_So function generates an VC-AIS, carrying the incoming AIS indication. K3[5-6] bits are set by definition to “11” value
102. Internal TC_So behaves as if it were in normal conditions: k3[5-6] bits are overwritten to the value “11”
103. Upon detection of C2=“FF” and K3[5-6]=“11”, the ITC_TT_Sk function detects an incoming VC-AIS (I.e. normal condition): no protection mechanism is triggered within the domain and no consequent action is performed.

With reference to FIG. 11, an external failure condition is illustrated.
111. Upon detection of an SSF condition (incoming AIS), the ITC_TT_So function generates an internal VC-AIS, carrying the indication of detected failure (K3[5-6]=“10”) at ingress node (K3[1-4]=“1111”).
112. Upon detection of C2=“FF” and K3[5-6]=“10” and K3[1-4]=“1111”, the ITC_TT_Sk function detects that an external failure occurred: no protection mechanism is triggered within the domain and an AU-AIS signal is generated.

With reference to FIG. 12, an internal failure condition is illustrated.
121. Internal TC_So generates K3[5-6] to “11” value. Node C, detecting a failure, generates IVC_AIS carrying the indication of detected failure (K3[5-6]=“10”) at its input (K3[1-4]=C) and generates RDI indication to be inserted.
123. Node C, in backward direction, insert a Remote Defect Indication (K3[5-6]=“01”) detected at node C (K3[1-4]=C).
124. The ITC_TT_Sk function detects RDI indication carried over K3[5-6], indicating that a failure occurred between nodes B and C: possibly a protection mechanism is triggered within the network domain B.
125. Upon detection of IVC-AIS, the ITC_TT_Sk function detects an internal failure occurred before node C: the possible protection mechanism is triggered within the domain and AU-AIS is regenerated.

With reference to FIG. 13, an internal failure condition with backward failure is illustrated.
131. ITC_Sk in node A detects both remote and forward defect indication. With the received node identifier it is possible to state that the failure occurred before node B in forward direction and between A and D in backward direction.
132. ITC_Sk in node D detects both remote and forward defect indication. With the received node identifier it is possible to state that the failure occurred before node C in forward direction and between D and A in backward direction.

Finally, with reference to FIG. 14, an external failure condition with backward failure is illustrated.
141. The ITC_TT_Sk function detects RDI indication and failure carried over K3[5-6], indicating that a failure occurred between nodes B and C.
142. ITC_Sk in node D detects forward defect indication. With the received node identifier it is possible to state that the failure occurred before node C in forward direction and between D and A in backward direction.
143. Node C, in backward direction, insert a Remote Defect Indication (K3[5-6]=“00”) detected at node C (K3[1-4]=C) to be added to the failure indication.

It has now become clear that the new solution solves the problem of fault detection/fault localization in network with nested domains, optimizing network element response with respect the use of control plane.

There have thus been shown and described a novel method and a novel frame which fulfill all the objects and advantages sought therefore. Many changes, modifications, variations and other uses and applications of the subject invention will, however, become apparent to those skilled in the art after considering the specification and the accompanying drawings which disclose preferred embodiments thereof. All such changes, modifications, variations and other uses and applications which do not depart from the scope of the invention are deemed to be covered by the invention which is limited only by the claims which follow.

1. A method for in-band path failure detection localization in a SDH/SONET network, the network comprising at least one network domain, the method comprising the steps of defining at least one path through which SDH/SONET frames are transmitted and coding K3 byte of POH, for SDH technology, or coding the Z4 byte of STS1 POH, for SONET technology.

2. The method according to claim 1, wherein the step of coding byte K3 or byte Z4 of the Virtual Container POH of the SDH/SONET frames comprises the step of coding at least one of the fifth and sixth bits thereof.

3. The method according to claim 1, wherein the step of coding byte K3 or byte Z4 of the Virtual Container POH of the SDH/SONET frames comprises the step of providing Remote Defect Indication information.

4. The method according to claim 1, wherein the step of coding byte K3 or byte Z4 of the Virtual Container POH of the SDH/SONET frames comprises the step of providing information relating to the fact that a failure is external or internal to a network domain.

5. The method according to claim 2, wherein both the fifth and sixth bits of the byte K3 or Z4 are coded according to the following coding:
11: no failure condition detected in ingress node and no consequent action is taken on payload;
10: external failure, namely a failure is detected in ingress node or a domain; an internal VC-AIS is injected in ingress node;
01: failure Detected in backward direction; no consequent action is taken on payload; and
00: failure Detected in ingress node and failure detected in backward direction; an internal VC-AIS is injected in ingress node.

6. The method according to claim 1, wherein bits 1-4 of byte K3 o Z4 are coded so that they carry a node identifier indicating a node detecting a failure.

7. The method according to claim 1, wherein a multiframe arrangement may be supported for network domains comprising more than sixteen nodes.

8. A SDH/SONET frame for providing in-band path failure detection localization in a SDH/SONET network, the frame comprising a POH and a payload, the POH comprising a number of bytes, wherein at least one part of byte K3 or byte Z4 of the POH is coded in order to determine whether a High Order path failure occurred inside a given domain or outside.

9. The frame according to claim 8, wherein the fifth and sixth bits of byte K3 or Z4 of the POH are coded by providing Remote Defect Indication information and information relating to the fact that a failure is external or internal to a network domain.

10. A frame according to claim 8, wherein both the fifth and sixth bits of the said byte K3 or Z4 are coded according to the following coding:
11: no failure condition detected in ingress node and no consequent action is taken on payload;
10: external failure, namely a failure is detected in ingress node or a domain; an internal VC-AIS is injected in ingress node;
01: failure Detected in backward direction; no consequent action is taken on payload; and
00: failure Detected in ingress node and failure detected in backward direction; an internal VC-AIS is injected in ingress node.

11. The frame according to claim 8, wherein bits 1-4 of byte K3 o Z4 are coded so that they carry a node identifier indicating a node detecting a failure.
